(19) United States
(12) Patent Application Publication
(10) Pub. No.: US 2010/0132787 A1
(43) Pub. Date: Jun. 3, 2010

(54) ACTIVE SOLAR CELL AND METHOD OF MANUFACTURE

(75) Inventor: Mikko Vaananen, Espoo (FI)

Correspondence Address: YOUNG & THOMPSON, 209 Madison Street, Suite 500, Alexandria, VA, 22314, US

(73) Assignee: SUINNO OY, Helsinki (FI)

(21) Appl. No.: 12/594,295

(22) PCT Filed: Apr. 2, 2008
(86) PCT No.: PCT/EP08/53942

§ 371 Date: Oct. 1, 2009

(30) Foreign Application Priority Data
Apr. 4, 2007 (FI) 20070264

(51) Int. Cl. H01L 31/00

(52) U.S. Cl. 136/256

(57) ABSTRACT

Devices and methods for improving the efficiency of solar cells, and a solar cell thereof. One aspect involves a solar cell with a semiconductor layer (11, 12, 13, 14, 15, 16, 17) with a natural band gap NB (NB2, NB3, NB4, NB5, NB6, NB7). This semiconductor layer also has at least one electrode (100, 101, 110, 111, 120, 121) designed to produce an ambient voltage V (V1, V2, V3, V4, V5, V6, V7) into the layer. The incoming photons therefore experience a modified NB−V=B band gap (B1, B2, B3, B4, B5, B6, B7), referred here to as the apparent band gap. Photons with E>B1 will be absorbed into the band gap B, and the electron in the semiconductor valence band will get excited onto the conduction band thus resulting in photocurrent. The ability to tune the apparent band gap B provides an enormous strength to optimize the incoming photon collection.

### TECHNICAL FIELD OF INVENTION

The invention relates to the field of solar cells. In particular, the invention relates to devices and methods for improving the efficiency of solar cells, and a solar cell thereof.

### BACKGROUND

The efficiency of solar cells is currently so low, that solar energy has not been competitive against fossil fuels during low energy prices. Due to this many technologies have been proposed to make solar cells more efficient and thus increase the competitiveness of solar energy in the global marketplace.

EP 1724841 A1 describes a multilayer solar cell, wherein plural solar cell modules are incorporated and integrally laminated, so that different sensitivity wavelength bands are so that the shorter the centre wavelength in the sensitivity wavelength band is, the more near the module is located to the incidental side of sunlight. This document is cited here as reference.

It is known that in order for a photon to be absorbed into the band gap, and thus produce photocurrent, the energy of the photon has to be greater or equal to the band gap. Prior art solutions, EP 1724841 A1 included, have the clear disadvantage that they are unable to provide band gaps that would collect photons efficiently. A great majority of the photon population is simply wasted as heat.

### SUMMARY

The invention under study is directed towards a system and a method for effectively collecting the photons from solar light to photocurrent. A further object of the invention is to present a method of production with which more and more efficient solar cells can be designed.

In this application a semiconductor layer is construed as a layer of any material or comprising any material capable of experiencing the photoelectric effect.

One aspect of the invention involves a solar cell with a semiconductor layer with a natural band gap NB1. This semiconductor layer also has at least one electrode designed to produce an ambient voltage V1 into the layer. The incoming photons therefore experience a modified NB1−V1=B1 band gap, referred here to as the apparent band gap. Photons with E>B1 will be absorbed into the band gap B1, and the electron in the semiconductor valence band will get excited onto the conduction band thus resulting in photocurrent. In accordance with the invention, the ability to tune the apparent band gap B1 provides an enormous strength to optimise the incoming photon collection.

The photon population that is not absorbed consists of photons with E<B1 that had too little an energy to get absorbed. Additionally the photons that got absorbed with E>B1 will only give out an energy equal to the apparent band gap B1 in the excitation process of the electron to the photocurrent. The remaining energy E−B1 will be emitted as a secondary photon of energy E2=E−B1 or multiple photons among which energy E2=E−B1 is distributed in accordance with the laws of conservation of energy and momentum and quantum mechanics. These two groups, photons with E<B1 and E2=E−B1 belong to the secondary photon population.

It is also true that some of the photons with E>B1 will not get absorbed, because they are simply unable to find the valence electron and interact with it. This fraction is not influenced by the band gap, however. The number of missed E>B1 is a function of the concentration of the ion/atom/molecule species with the valence electron N1 and the scattering cross section of this electron. Also lattice packing density of the material, temperature etc. may have some effect. In one aspect of the invention the fraction of missed E>B1 in the semiconductor layer is minimised. This group of unabsorbed photons with E>B1 is further added to the secondary photon population.

According to a further aspect of the invention, the secondary photon population and some missed E>B1 photons will pass through the first semiconductor layer and enter a second semiconductor layer with natural band gap NB2. This semiconductor layer also may have at least one electrode designed to produce an ambient voltage V2 into the layer, producing the apparent band gap B2=NB2−V2. The ambient voltage can be used to raise or lower the energy state of the electron or electrons at the valence band. In accordance with the invention, the apparent band gap B2 is optimised to produce as much photocurrent as possible and as desirable a second secondary photon population as possible.

In further embodiments of the invention, multiple semiconductor layers with different band gaps are used. Some of the layers may have an ambient voltage in them. The ambient voltage may be produced by a voltage generator attached to at least one electrode. Some of the collected photocurrent can be fed back in to power the ambient voltages V1, V2 in some embodiments. In some embodiments the semiconductor layers with ambient voltages or without may have electrically insulating films or materials in between them, which are typically transparent to the photons.

With reference to what is explained before, multiple active (with ambient voltage) and passive (no ambient voltage) semiconductor layers can be laid over each other so, that each layer collects a certain part of the solar spectrum, or secondary photon population spectrum. As the use of ambient voltages allows some liberty in tuning to a desired part of the solar spectrum or secondary photon population spectrum, the entire solar spectrum photons can be carefully collected, by collecting the maximum number of photocurrent and producing the minimum number of secondary photons with E> minimum band gap. The secondary photons with E> minimum band gap are typically dissipated as heat, because the photovoltaic system cannot absorb these because none of the photons can reach a band gap.

A further aspect of the invention involves the manufacture of a solar cell system based on the previous principles in accordance with the invention. First, the solar spectrum is measured or known in accordance with the invention. The sunlight is then incident on the first semiconductor layer with band gap NB1, and the first semiconductor layer may be tuned with an ambient voltage to an apparent band gap B1. Also other factors such as dopant concentration, donor concentration, acceptor concentration, lattice constant etc. may be tuned. Typically the first semiconductor layer is transparent to all or some of the secondary photons. Then the resulting sunlight that emerges through the first semiconductor layer, i.e. the secondary photon population is recorded with a second spectrometer. The difference in spectra between the first and the second spectrometer gives the effect of the first semiconductor layer on the solar spectrum. This difference can also be compared with the derived photocurrent from first semiconductor layer, to deduce the efficiency of the first semiconductor layer.

By tuning the parameters of first semiconductor layer, different difference and secondary spectra and efficiencies may be explored in accordance with the invention. In some embodiments, the maximum overall efficiency is derived by maximising the photocurrent collection and maximising the fit of the secondary photon population spectra to the band gap B2 and other parameters of the second semiconductor layer, which is behind the first semiconductor layer. It is clear that multiple layers can be designed in this way, preferably always optimising photocurrent collection at the layer and the fit of the secondary photon population spectra with the response of each subsequent layer.

By the response of the semiconductor layer we mean the way in which the semiconductor responds to an incoming photon spectrum, i.e. how many photons converted to photocurrent at a specific energy, how many photons pass through without interaction at a specific energy, how many photons with E>B1 pass through at a specific energy, how many photons with E<B1 pass through at a specific energy, what is the shape of the secondary photon spectra at a specific energy etc. All or some of these variables also define the bolometric response of the semiconductor layer, i.e. how many photons converted to photocurrent across all energies, how many photons pass through without interaction across all energies, how many photons with E>B1 pass through across all energies, how many photons with E<B1 pass through across all energies, what is the shape of the secondary photon spectra across all energies etc.

It is the objective of the invention to produce a semiconductor layer “sandwich” of multiple layers, each with a response that maximises the collected photocurrent and produces a secondary photon population spectra that has the maximum fit with the response of the subsequent semiconductor layer. Both the collected photocurrent and the secondary photon population spectra can be tuned by the material characteristics, and beyond the material characteristics by tuning the natural band gap with an ambient voltage to an apparent band gap that optimises the collected photocurrent and the secondary photon population spectra. When this optimisation is done for several semiconductor layers, each assigned to different small bands in the solar spectrum, the maximum number of photons can be collected throughout the whole solar spectrum that can be harnessed by photoelectric effect, thereby boosting efficiency of the solar cell system.

A solar cell in accordance with the invention comprises at least one first semiconductor layer with a natural band gap NB arranged to convert incoming photons to electric current and is characterised in that,
at least one semiconductor layer is provided with at least one electrode,
the at least one electrode is arranged to provide an ambient voltage V in the semiconductor layer,
the ambient voltage V is arranged to tune the natural band gap NB to apparent band gap B by B=NB−V,
the semiconductor layer with apparent band gap B is arranged to convert a first photon population from the incident photons to photocurrent and leave secondary photon population.

A method for operating a solar cell in accordance with the invention, comprises the following steps,
raw solar spectrum incident on first semiconductor layer with band gap NB1,
adjust NB1 by tuning the ambient voltage V1 in the first semiconductor layer to band gap B1,
photons with energy E<B1 pass through the first semiconductor layer,
photons with energy E>B1 get absorbed and converted to photocurrent, secondary photons left with E−B1 remain from the absorbed photons,
photons with E<B1 and secondary photons with E=E−B1 are incident on second semiconductor layer with band gap NB2.
A method for producing a solar cell in accordance with the invention comprises the following steps,
record solar spectrum with spectrometer 1,
sunlight incident on first semiconductor layer with natural band gap NB1,
adjust NB1 by tuning the ambient voltage V1 and other variables to band gap B1,
record spectrum of resulting unabsorbed sunlight with spectrometer 2,
resulting sunlight is incident on second semiconductor layer with natural band gap NB2,
adjust NB2 by tuning ambient voltage V2 and other variables.

A solar cell with at least two semiconductor layers in accordance with the invention is characterised in that,
the first layer closest to incident solar radiation is a InGaP and/or GaN layer,
the second layer is a polycrystalline silicon layer and/or InSb layer.

In addition and with reference to the aforementioned advantage accruing embodiments, the best mode of the invention is considered to be a multilayer solar cell where some layers have an ambient voltage tuning the natural band gap and some layers are at their natural band gap, and where the overall photocurrent collection of the multilayer solar cell is maximised by optimising the response of each semiconductor layer with respect to the incoming spectra and the secondary photon population spectra and the response of the following layer to this secondary photon population spectra.

### BRIEF DESCRIPTION OF THE DRAWINGS

In the following the invention will be described in greater detail with reference to exemplary embodiments in accordance with the accompanying drawings, in which

FIG. 1 demonstrates an embodiment 10 of the inventive solar cell arrangement as a block diagram.

FIG. 2 demonstrates an embodiment 20 of the inventive solar cell with an alternative ambient voltage electrode arrangement as a block diagram.

FIG. 3 demonstrates an embodiment 30 of the inventive multilayer solar cell with an alternative ambient voltage electrode arrangement with reference to the solar spectrum as a block diagram.

FIG. 3B demonstrates an embodiment 31 of the inventive multilayer solar cell as a cross-sectional block diagram.

FIG. 4 demonstrates an embodiment 40 of the inventive multilayer solar cell with an alternative reference to the solar spectrum as a block diagram.

FIG. 5 demonstrates an embodiment 50 of the inventive multilayer solar cell with several dedicated bands in the solar spectrum as a block diagram.

FIG. 6 demonstrates an embodiment 60 of the operation of an inventive multilayer solar cell as a flow diagram.

FIG. 7 demonstrates an embodiment 70 of the manufacturing process of an inventive multilayer solar cell as a flow diagram.

FIG. 8 demonstrates an embodiment 80 of the manufacturing arrangement for the manufacture of an inventive multilayer solar cell as a block diagram.

FIG. 9 shows an embodiment of the p-n junction of the invention in detail.

Some of the embodiments are described in the dependent claims.

### DETAILED DESCRIPTION OF EMBODIMENTS

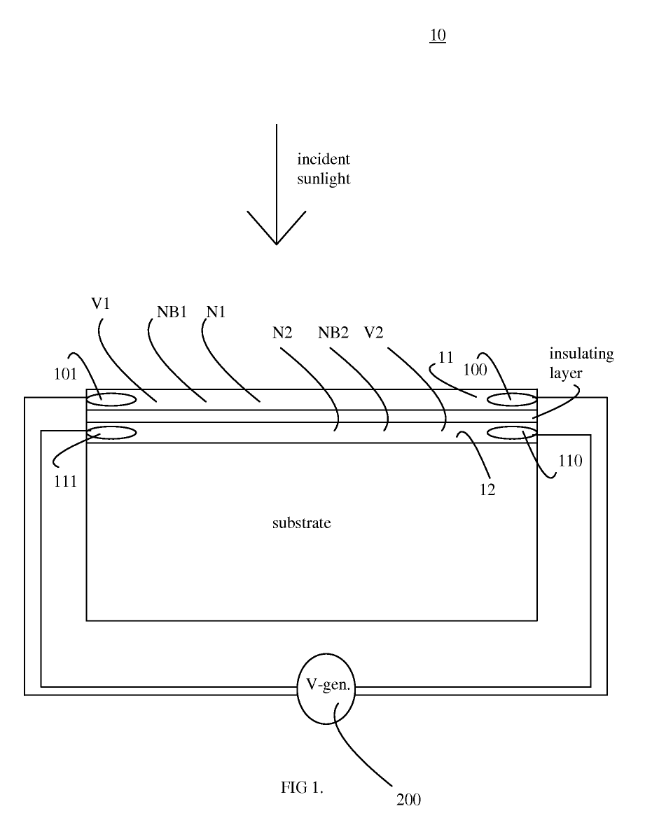

FIG. 1 discloses a solar cell in accordance with the invention having two layers. The first layer 11 on the side of incident sunlight has a natural band gap of NB1, and a concentration N1 of the atom/ion/molecule species with this band gap. The semiconductor layer 11 or any subsequent layer mentioned in this application (12, 13, 14, 15, 16, 17, layer 1, layer 2) may feature any element or alloy combination, or any material capable of photoelectric effect in accordance with the invention. For example the semiconductor layer 11, or any subsequent layer mentioned in this application (12, 13, 14, 15, 16, 17, layer 1, layer 2) may contain Si (Silicon), polycrystalline silicon, thin-film silicon, amorphous silicon, Ge (Germanium), GaAs (Gallium Arsenide), GaAlAs (Gallium Aluminum Arsenide), GaAlAs/GaAs, GaP (Gallium Phosphide), InGaAs (Indium Gallium Arsenic), InP (Indium phosphide), InGaAs/InP, GaAsP (Gallium Arsenic Phosphide) GaAsP/GaP, CdS (Cadmium Sulphide), CIS (Copper Indium Diselenide), CdTe (Cadmium Telluride), InGaP (Indium Gallium Phosphide) AlGaInP (Aluminium Gallium Indium Phosphide), InSb (Indium Antimonide), CIGS (Copper Indium/Gallium diselenide) and/or InGaN (Indium Gallium Nitride) in accordance with the invention. Likewise the semiconductor layer 11 or any subsequent layer mentioned in this application (12, 13, 14, 15, 16, 17, layer 1, layer 2) may feature any element or alloy combination, or any material capable of photoelectric effect described in the publications EP 1724 841 A1, Josuke Nakata, “Multilayer Solar Cell”, U.S. Pat. No. 6,320,117, James P. Campbell et al., “Transparent solar cell and method of fabrication”, Solar Electricity, Thomas Markvart, 2^{nd} Edition, ISBN 0-471-98852-9 and “An unexpected discovery could yield a full spectrum solar cell, Paul Preuss, Research News, Lawrence Berkeley National Laboratory, which publications are all incorporated into this application by reference in accordance with the invention.

The semiconductor layer 11 or any subsequent layer mentioned in this application (12, 13, 14, 15, 16, 17, layer 1, layer 2) typically manufactured and/or grown by lithography, molecular beam epitaxy (MBE) metalorganic vapour phase epitaxy (MOVPE), Czochralski (CZ) silicon crystal growth method, Edge-define film-fed growth (EFG) method, Float-zone silicon crystal growth method, Ingot growth method and/or Liquid phase epitaxy, (LPE). Any fabrication method described in the references EP 1724 841 A1, Josuke Nakata, “Multilayer Solar Cell”, U.S. Pat. No. 6,320,117, James P. Campbell et al., “Transparent solar cell and method of fabrication”, Solar Electricity, Thomas Markvart, 2^{nd} Edition, ISBN 0-471-98852-9 and “An unexpected discovery could yield a full spectrum solar cell, Paul Preuss, Research News, Lawrence Berkeley National Laboratory, can be applied to produce a solar cell in accordance with the invention. Any other fabrication method can also be applied to produce a solar cell in accordance with the invention.

The semiconductor layer 11 also contains electrodes 100 and 101 that provide an ambient voltage V1 inside the semiconductor layer, thereby producing an apparent band gap of B1=NB1−V1 between the valence and conduction bands of the atom/ion/molecule species. The electrodes 100 and 101 are typically connected to the voltage generator 200 that generates the ambient voltage V1 into the first layer 11.

The electrodes and electrical contacts are typically manufactured and/or grown into the semiconductor layer 11 by screen printing, as explained in Solar Electricity, Thomas Markvart, 2^{nd} Edition, ISBN 0-471-98852-9 or by any other method in accordance with the invention.

In some embodiments the solar cell also has an antireflection coating on top of semiconductor 11, which antireflection coating can be for example of titanium oxide (TiO₂) and/or Silicon Nitride Si₃N₄ or of any other mentioned in the references and/or any material in accordance with the invention.

The ambient voltage can be generated from electrodes that face each other in a direction opposite to the line of incident sunlight as shown here, or in fact any direction. The important thing is that they provide an ambient voltage, which should preferably be quite homogeneous across the entire first semiconductor layer 11. Some photons of the incident sunlight with E>B1 will be absorbed and converted to photocurrent, whereas some photons with E>B1 may fail to interact with electrons in the valence band, and photons with E<B1 will also pass through. The unabsorbed photons, i.e. the secondary photon population, or some of them, will pass through the electrically insulating layer and enter the second semiconductor layer 12. The insulating layer is typically a transparent material to the secondary photon population, and is made for example from, plastic film, rubber or any other material.

In some embodiments there is no insulating layer. The purpose of the insulating layer is to electrically insulate the two semiconductor layers 11 and 12 so that the ambient voltages V1 and V2 provided by the electrodes 100, 101 and 110, 111 can be controlled accurately in each layer 11 and 12, without them interfering with each other. If there is no need to prevent interference, for example in the case where V1=V2, or V1=V2=0, or the ambient voltage is allowed to distribute freely in the solar cell system 10, then there is no need for an electrically insulating layer between the two layers 11, 12 in some embodiments of the invention. The semiconductor layers 11, 12 are mounted on a substrate which can be of any material, for example a semiconductor material, glass, plastic, rubber, plastic film or the like in accordance with the invention in some embodiments.

The solar cell system 10 can be realised as a stiff solar panel, or it can also be realised as a flexible thin film solar cell, that is easily shaped on various surfaces. The electrodes 100, 101, 110, 111 can be arranged to also collect the photocurrent from the semiconductor layers 11 and 12 in some embodiments of the invention, or other dedicated electrodes may be arranged to handle the photocurrent collection.

In some embodiments the voltage generator 200 is powered with the energy that is derived from the collected photocurrent. Thus the solar cell system 10 is capable of feeding back a portion of its collected solar energy to improve the efficiency to produce more solar energy further still in this embodiment of the invention.

Quite obviously an embodiment where either or both of the semiconductor layers 11 and 12 do not have an ambient voltage or associated electrodes is also in accordance with the invention. For example in some embodiments the semiconductor layer 11 may be at its natural band gap, but the apparent band gap of B2 is tuned from NB2 by V2 to collect the secondary photon population entering semiconductor layer 12 better than without the tuning, i.e. at natural band gap NB2.

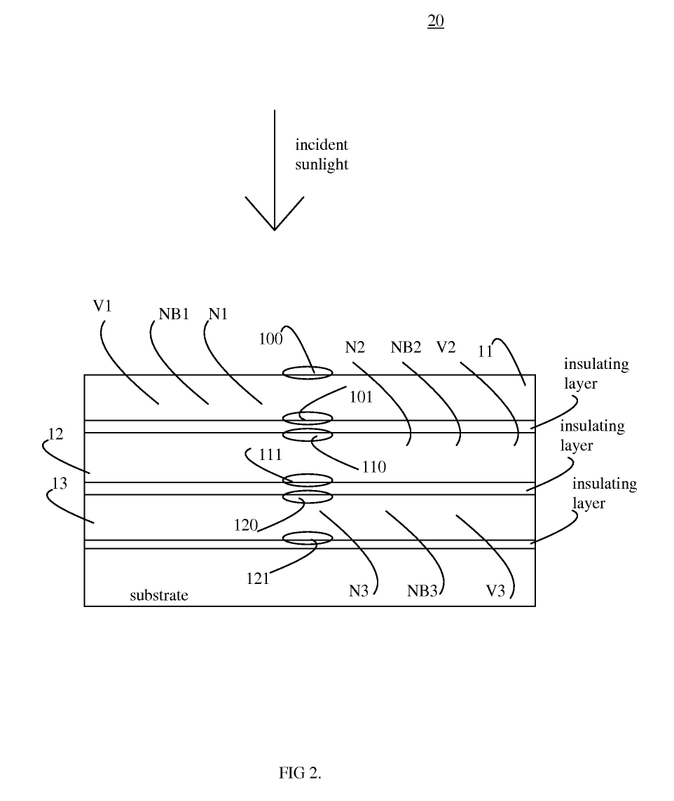

FIG. 2 discloses an alternative solar cell system 20 with a different electrode arrangement and three semiconductor layers 11, 12 and 13. In this embodiment the electrodes 100, 101, 110, 111, 120 and 121 are arranged in line with incident sunlight. Quite clearly, any distribution of (1→n=large number) electrodes is possible in any configuration providing an ambient voltage in accordance with the invention. The semiconductor layers 11, 12 and 13 and electrodes 100, 101, 110, 111, 120 and 121 insulating layers and substrates may be designed and/or optimised to cope with both line parallel solar radiation or solar light at any incidence angle, and/or scattered and/or polarised solar radiation, or any light whatsoever, in accordance with the invention.

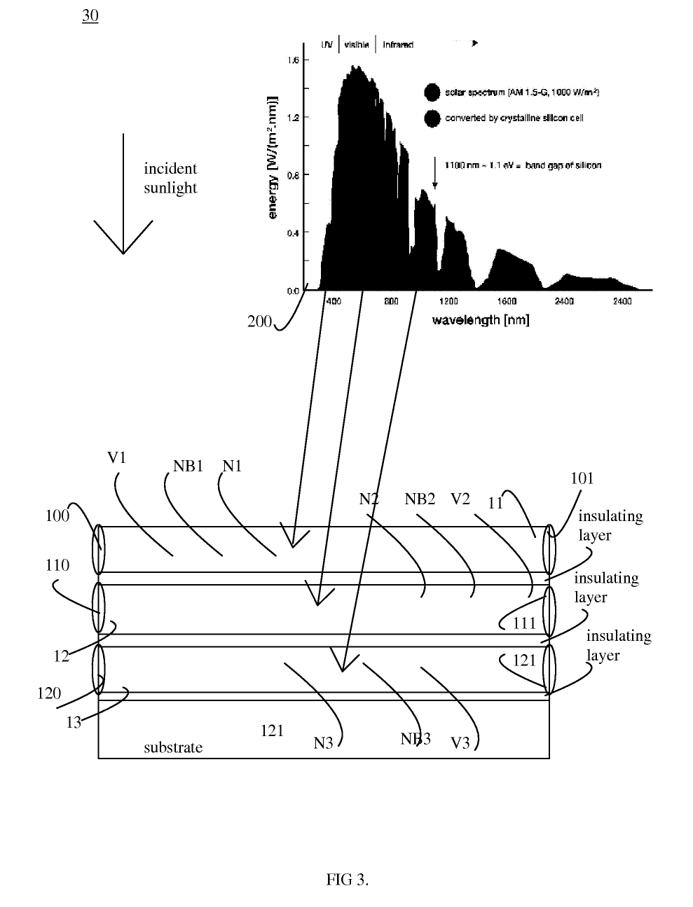

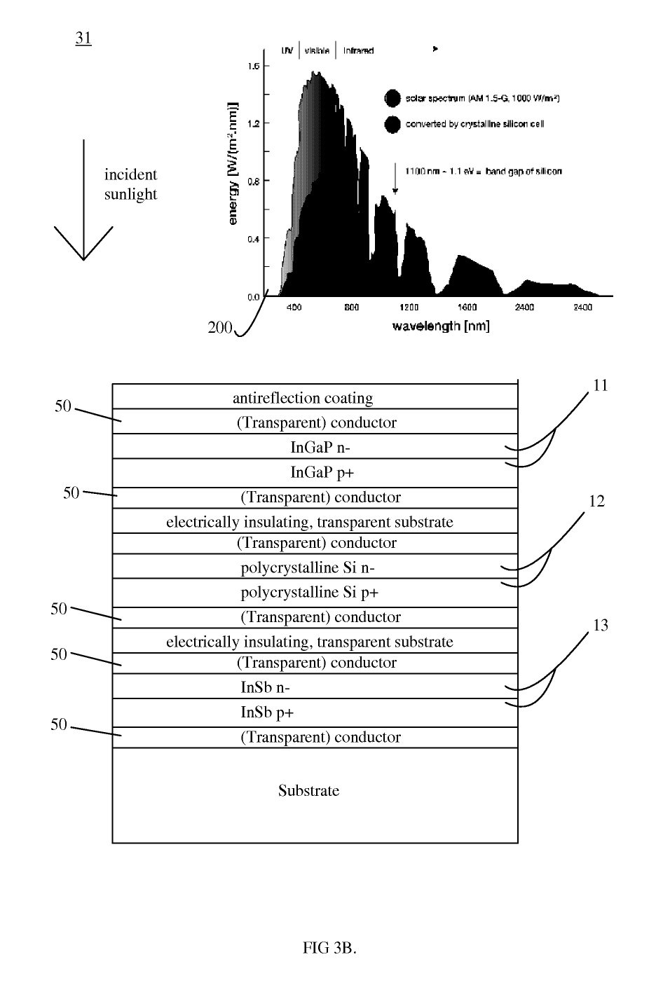

FIG. 3 shows an embodiment of a solar cell comprising three semiconductor layers 11, 12, 13 in an order where the bigger band gaps are closer to the incident solar spectrum. Semiconductor layer 11 is tuned to the UV-band, approx 200-400 nm of wavelength. It will thus have a natural band gap NB1 of about 6.2-3.1 eV (electrovolt). This natural band gap NB1 can further be tuned to an apparent band gap B1 if it fits the high energy end of the solar spectrum better. For the purposes of demonstration in accordance with the invention, let's assume that layer 11 has a natural band gap of 4.65 eV. It is decided that there is no need for an ambient voltage V1=0. Photons with E>4.65 eV can thus be absorbed from the spectrum 200, corresponding to the part of the spectrum on the left from roughly 260 nm. Thus, for example from a photon of 6.2 eV at roughly 200 nm 4.65 eV will be used to excite an electron from the valence band in the semiconductor layer 11 to the conduction band. An electron in the conduction band thus amounts to the photocurrent i.e. solar electric energy that can be extracted from the system to power any applications. To conserve energy, a photon of 1.55 eV will be released in the process. In some situations in accordance with the invention more than one secondary photons can be emitted, for example two with say for example 0.775 eV each, in accordance with the invention and the energy and momentum conservation laws of quantum mechanics. For the purposes of further illustration lets say there is one 1.55 eV photon left to the secondary photon population. This photon is arranged to pass through the insulating layer in between the first 11 and the second 12 semiconductor layers. This photon enters the second semiconductor layer with a wavelength of roughly 790 nm. Let's assume that NB2=1.68 eV for the purposes of illustrating the invention. The electrodes 110 and 111 set at the ends of the layer provide an ambient voltage V2 of −0.13 eV. The ambient voltage is preferably low, and providing it does not consume much energy. The apparent band gap B2 in the second semiconductor layer arrives exactly at 1.55 eV. What is the consequence? The secondary photon of 1.55 eV will get absorbed, an electron is excited to the conduction band from the valence band and more solar energy is provided in the form of photocurrent. There will not be any secondary photons left from this absorption. What would have happened, had there not been the tuning provided by the ambient voltage V2? The 1.55 eV photon would have passed through the second semiconductor layer, the insulating layer if there is one, and would have arrived at the third semiconductor layer 13. Tuning the apparent band gap up, i.e. the band gap experienced by the incoming photons, can be used to catch more energy of the higher E photons earlier. Tuning the appararent band gap down can be used to catch lower E photons that would not be possible to catch with the natural (too high) band gap.

Let's assume that the natural band gap NB3=0.935 eV, equalling roughly 1300 nm in wavelength. For the purposes of illustrating the invention, further assume ambient voltage V3=0.16 eV, amounting to apparent band gap B3=0.775 eV. Things do not look very good for the 1.55 eV photon that did not get absorbed at the second semiconductor layer. It can get absorbed, but it will either leave one 0.775 eV photon to hunt for another absorption in third semiconductor layer, which it might not get and which is less probable, or two 0.388 eV photons that cannot get absorbed and will be dissipated as heat.

Things look better for the two secondary 0.775 eV photons that could have been left at the first semiconductor layer 11. They pass through the second semiconductor layer 12 and have only to get one absorption process from the third semiconductor layer, and they have converted their energy to photocurrent and solar energy with 100% efficiency. To explain, it is comparatively more probable for a photon to get absorbed once rather than to get absorbed once AND the secondary photon to also get absorbed.

As is above clearly explained the semiconductor layers can be tuned by the ambient voltages to maximise the overall photocurrent, by optimising the photocurrent and the most desirable secondary photon population spectra at each stage in accordance with the invention.

FIG. 3B discloses the solar cell also has an antireflection coating on top of semiconductor layer 11, 12, 13, which antireflection coating can be for example of titanium oxide (TiO₂) and/or Silicon Nitride Si₃N₄ or of any other mentioned in the references and/or any material in accordance with the invention.

The next layer comprises the electrical contacts 50, or a electrical conductor layer 50 needed to transport the collected photocurrent. The electrodes providing ambient voltage 100, 101, 110, 111, 120, 121 and electrical contacts 50 are typically manufactured and/or grown into the semiconductor layers 11, 12, 13, by screen printing, as explained in Solar Electricity, Thomas Markvart, 2^{nd} Edition, ISBN 0-471-98852-9 or by any other method in accordance with the invention. Alternatively, they could be implemented as a separate layer on top the semiconductor layers 11, 12, 13 in some embodiments. In this embodiment the conductor layer is typically transparent in accordance with the invention. The electrical contacts and/or the electrodes preferably occupy the minimum area when meshed with the semiconductor layers 11 12 and/or 13. Semiconductor layer 11 is typically InGaP-layer at approximately band gap 1.93 eV in this embodiment. Alternatively, in some embodiments the semiconductor layer could be realised with a GaN-layer, preferably with a band gap of 3.4 eV in accordance with the invention.

The next semiconductor layer 12 is typically of polycrystalline silicon at band gap of 1.1 eV, and the third semiconductor layer is typically of InSb at a band gap of 0.17 eV. The three layers 11, 12, 13 provide an impressive dynamic range of 0.17-3.4 eV by their natural band gaps, which dynamic range can still be further enhanced by providing at least one ambient voltages V1, V2 and/or V3 to the layers 11, 12 and/or 13. The photon statistics work as explained in FIG. 3 and other figures in accordance with the invention. It is in accordance with the invention to omit at least one layer 11, 12, 13 or replace at least one layer 11, 12, 13 with another semiconductor material. It is also in accordance with the invention to add at least one further semiconductor layer to the semiconductor layers 11, 12, 13. For example adding a amorphous silicon layer at 1.75 eV band gap, a CdTe layer at 1.45 eV band gap, GaAs layer at 1.42 eV band gap, InP layer at 1.34 band gap and a CuInSe₂ (Copper Indium diselenide) layer at 1.05 eV band gap could provide the ultimate “monster sandwich” of solar cells, i.e. a solar cell with great efficiency and great dynamic range in accordance with the invention. It is also in accordance with the invention to take one semiconductor material only, say polycrystalline silicon, and make all the layers 11, 12, 13 from this same material, and simply provide different band gaps by providing a different ambient voltage to each layer 11, 12, 13.

In some embodiments the need for insulating layers is entirely optional, in these embodiments some or all of the insulating layers can be omitted in accordance with the invention. The ambient voltage can also be arranged to vary within the semiconductor layer 11, 12, 13 in some embodiments, for example from one edge of the layer to another edge of the layer, there by causing a distribution of band gaps in the layer. For example, if the ambient voltage varies by +/−V, then there would be a distribution of band gaps in the material, broadened by 2V from the natural band gap.

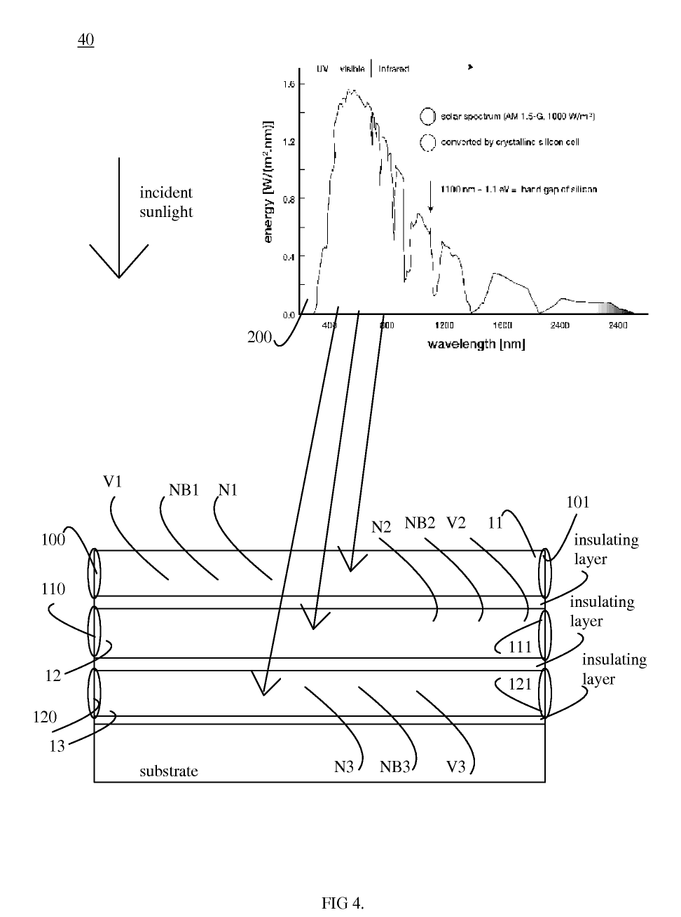

FIG. 4 discloses a solar cell that comprises three semiconductor layers with in an order where the smaller band gaps are closer to the incident solar spectrum. Again the invention is explained with reference to non-restrictive examples. Let's assume natural band gap NB1=0.775 eV with ambient voltage of V1=0.16 eV amounting to 0.935 eV for the apparent band gap B1. All photons to the left of 1300 nm can get absorbed giving away 0.935 eV to the photocurrent. However, there are a lot of photons to interact with few ions, so not all of them can necessarily get absorbed, and also those photons that get absorbed leave high energy secondary photons: for example a photon with E=6.2 eV would leave a secondary photon of 5.28 eV, or several among which 5.28 eV is distributed. Some of the photons that do not get absorbed pass through to layer 12, where they may have for example an apparent band gap of 2.79 eV. Photons of higher energy than this can get absorbed, but at the third level with apparent band gap of B3=5.28 eV only the unabsorbed or those photons that got absorbed only once at the first semiconductor layer 11 can get absorbed. This is not a very desirable situation if a lot of high energy photons end up at the third layer with E<5.28 eV and without getting absorbed. Quite clearly it is in accordance with the invention to maximise the energy absorbed from the photons by optimising the apparent band gaps with regard to the photon population at each level. In accordance with the invention, the less photons with high energy at the end of the process, the better.

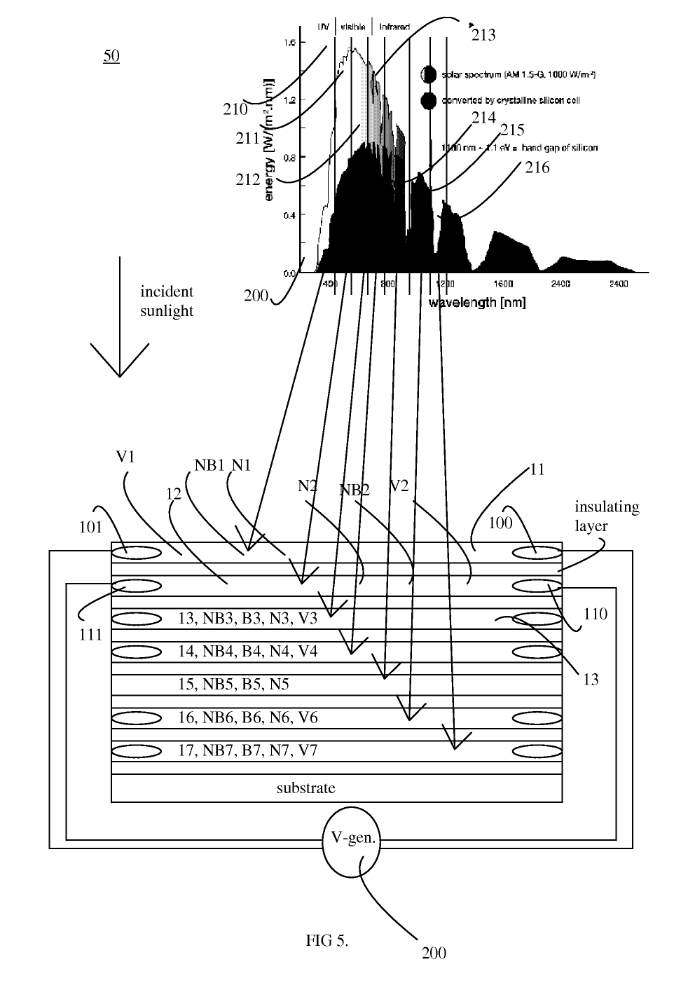

FIG. 5 shows an embodiment 50 of the multilayer solar cell with more layers. More layers increase the number of different band gaps and thereby the possibility for photons of different energies to get absorbed. FIG. 5 shows quite tight bands 210, 211, 212, 213, 214, 215 and 216 in the spectra that are assigned to the sensitivity i.e. apparent band gap of a semiconductor layer 11, 12, 13, 14, 15, 16 and 17. It is in accordance with the invention that there may be any number of layers, any number of assigned bands and any band may be assigned to any layer in some embodiments. The semiconductor layers 11, 12, 13, 14, 15, 16 and 17 may have varying thicknesses, not shown to scale.

The apparent band gaps B1, B2, B3, B4, B5, B6, B7 could be tuned into a sequence that optimises photon collection. Not all layers need not have ambient voltages induced by electrodes, some of the layers may be at their natural band gap, for example NB5=B5 in some embodiments. The ambient voltage is arranged to be used to adjust the band gap B1, B2, B3, B4, B5, B6, B7 of the semiconductor layer so that the band gap B1, B2, B3, B4, B5, B6, B7 is optimised with respect to the collected photocurrent, secondary photon population, the response of the subsequent semiconductor layer to the said secondary photon population, quantum efficiency of another possibly subsequent semiconductor layer and/or the energy consumed in providing the ambient voltage. The concentration of the atom/molecule/ion species and/or the thickness of the semiconductor layer is arranged to be optimised in this way also in some embodiments of the invention.

The layers are typically very thin, such as few nanometers at the slimmest or centimetres at their thickest in accordance with the invention. The layer thickness is typically in proportion to the photon population at that energy. If the photon population is a lot higher at E3=B3 than at E1=B1, then the thickness of the first semiconductor layer 11 can be slimmer than that of the third semiconductor layer 13. By similar argument, as more photons need more valence electrons to interact with, the concentration or total number of the atom/molecule/ion species could be higher for third semiconductor layer.

The apparent band gaps (B1-B7) could be set at for example 4.35, 3.73, 3.1, 2.48, 1.86, 1.24, 0.6 eV. One can calculate the photon populations layer (11-17) through layer (11-17) in the same way as shown for the embodiments 30 and 40. It is also in accordance with the invention to set the apparent band gaps so, that they guide a maximum population of the photons to the band where the layers or some layer has the best quantum efficiency. For example, if it is known that the quantum efficiency at 1.86 eV is great for layer 13, it is preferable to set the band gaps in preceding layers so that they form a maximum number of photons at 1.86 eV which can be used with great efficiency in accordance with the invention in some embodiments.

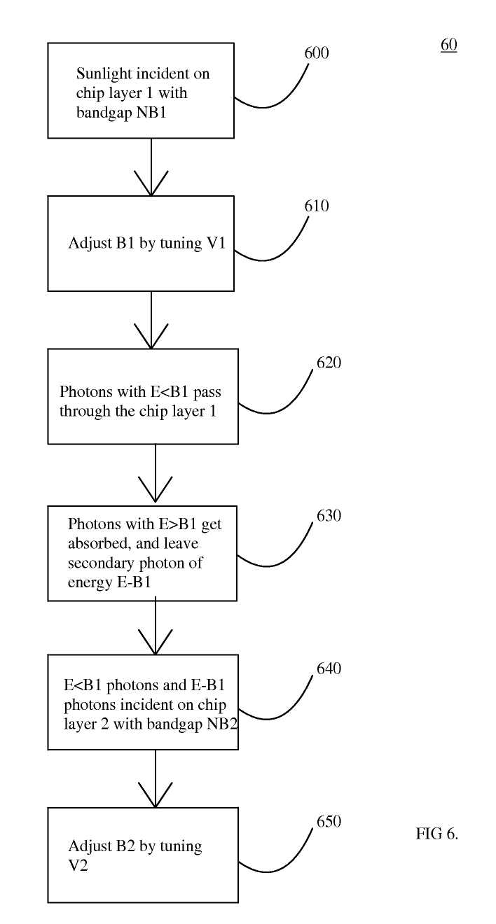

FIG. 6 shows the operation of the solar cell system in accordance with the invention as a flow diagram. Raw solar spectrum is incident on first semiconductor layer with natural band gap NB1 in phase 600. The NB1 is adjusted to B1 the apparent band gap by tuning the ambient voltage V1 in the first semiconductor layer 610. By tuning V1 and thus B1 it is possible to influence both the collected photocurrent and the secondary photon population at this phase. Typically B1 is optimised with respect to the collected photocurrent, secondary photon population, the response of the subsequent semiconductor layer to the said secondary photon population, quantum efficiency of another possibly subsequent semiconductor layer and/or the energy consumed in providing the ambient voltage.

In phase 620 photons with energy E<B1 pass through the first semiconductor layer. Some of the photons with energy E>B1 get absorbed and are converted to photocurrent in phase 630, secondary photons left with E−B1 of energy are left from the absorbed photons to conserve energy in phase 630. Photons with E<B1 and secondary photons with E=E−B1 are incident on second semiconductor layer with natural band gap NB2 in phase 640. Also those photons that had E>B1 but which did not get absorbed belong to this photon population, the secondary photon population consisting of at least the photons of these three groups is incident on the second semiconductor layer in phase 640 in some embodiments of the invention. In phase 650 the tuning of the apparent band gap B2 from the natural band gap is done by applying an ambient voltage V2.

As more semiconductor layers with the same natural and/or apparent band gaps are added to the system, the steps of 610, 620, 630, 640 are repeated for some or all of the subsequent semiconductor layers and natural band gaps in accordance with the invention.

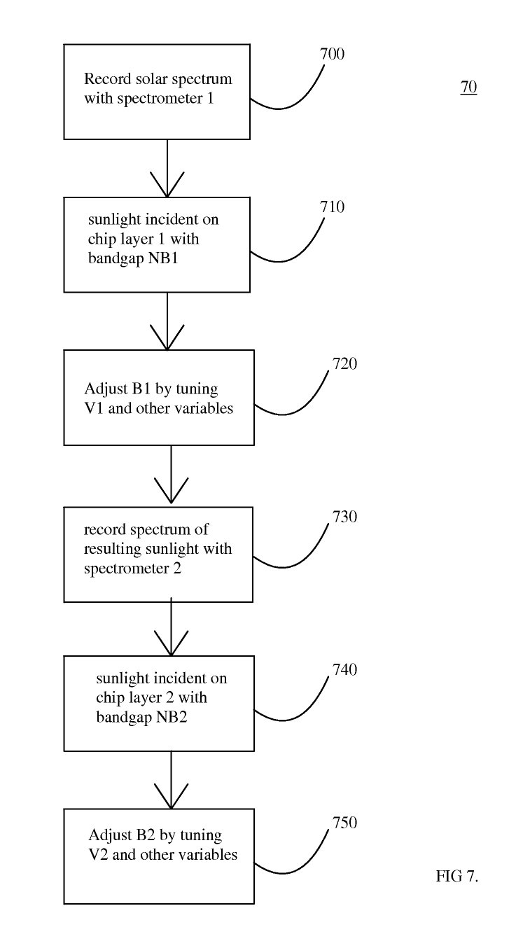

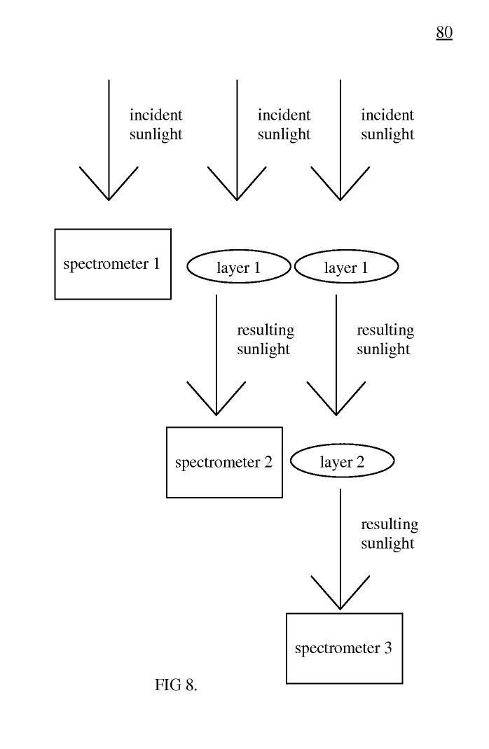

FIG. 7 shows a method of manufacturing the solar cell system in accordance with the invention as a flow diagram, and FIG. 8 shows an arrangement used in the manufacturing process. In phase 700 of FIG. 7 the solar spectrum with spectrometer 1 is recorded or known from previous measurements or literature. In phase 710 solar radiation is incident on first semiconductor layer with natural band gap NB1 shown as layer 1 in FIG. 8.

In phase 720 NB1 the natural band gap is adjusted by tuning the concentration N or total number of the atom/molecule/ion species in the semiconductor layer 1 of FIG. 8, layer 1 thickness, or the actual atom/molecule/ion species itself to obtain an optimum natural band gap NB1 for the solar spectrum. Consequently these other variables are used obtain NB1 and then the ambient voltage V1 is used to adjust the apparent band gap B1=NB1−V1 in phase 720. In phase 730 the spectrum of resulting unabsorbed sunlight is recorded with spectrometer 2 of FIG. 8. In some embodiments spectrometer 1 and spectrometer 2 are in fact the same device, just used in a different occasion. In phase 740 the resulting solar radiation (=secondary photon population spectra) is incident on second semiconductor layer, layer 2 of FIG. 8, with natural band gap NB2.

In phase 750 NB2 the natural band gap is adjusted by tuning the concentration N or total number of the atom/molecule/ion species in the semiconductor layer 2 of FIG. 8, layer 2 thickness, or the actual atom/molecule/ion species itself to obtain an optimum natural band gap NB2 for the secondary photon population spectrum. Consequently these other variables are used obtain NB2 and then the ambient voltage V2 is used to adjust the apparent band gap B2=NB2−V2 in phase 750. The spectrum of resulting unabsorbed sunlight from the secondary photon population is recorded with spectrometer 3 of FIG. 8. In some embodiments of the invention spectrometer 1, 2 and/or 3 are in fact the same device, just used in a different occasion.

In phases 720 and/or 750 the ambient voltage and other variables are tuned to maximise the captured photocurrent from the incident sunlight and the fit of the resulting unabsorbed sunlight spectrum with the response of the next subsequent semiconductor layer. Typically NB1, NB2, B1 and/or B2 is optimised with respect to the collected photocurrent, secondary photon population, the response of the subsequent semiconductor layer to the said secondary photon population, quantum efficiency of another possibly subsequent semiconductor layer and/or the energy consumed in providing the ambient voltage V1 and/or V2.

It is within the scope of the invention that any embodiments 10, 20, 30, 40, 50, 60, 70 and/or 80 may be readily combined and or permuted. Any features explained in association with one embodiment 10, 20, 30, 40, 50, 60, 70 and/or 80 can be used with another embodiment 10, 20, 30, 40, 50, 60, 70 and/or 80 in accordance with the invention.

In some embodiments of the invention, the aim is simply to optimise the detector response of each layer to the spectrum emerging from the previous layer. In this embodiment there is not always a need for an ambient voltage V1. The invention may be practiced without an active cell or an ambient voltage by optimising the detector response of the next layer to the spectrum emerging from the previous layer which is composed of uninfluenced photons, scattered photons, recombined photons and photons from photon-phonon interactions. It is in accordance with the invention to also use an ambient voltage.

This embodiment is described in detail in the following. It has been described earlier that some photons simply pass through the first layer without interaction. It has also been explained before that there are some photons that scatter, but still emerge to the next layer. It has further been explained before that some photons that get absorbed produce more secondary photons to abide to conservation of energy and laws of quantum mechanics (recombined photons). What was not explained before is that not only do the recombined photons turn directly to IR-photons which are synonymous with heat radiation, they also heat the solar cell itself by causing thermal vibration in the material itself. The quanta of this vibration is the phonon. Because the solar cell cannot heat to infinite temperatures, i.e. it must be in thermodynamic equilibrium with its surroundings it must radiate some of the heat. Therefore the vibrational phonon quanta turn into new recombinant photon quanta, that may again be photoelectrically collected in accordance with the invention. It is in accordance with the invention to also optimise the band gaps of the materials with respect to these four photon populations, without necessarily using an ambient voltage.

The dopant concentration, acceptor concentration, donor concentration, lattice structure, temperature and/or relative concentrations of the semiconductor materials can all be optimised to deliver the best response to the spectrum emerging through the first semiconductor layer. It is in accordance with the invention to run tests with different thermal environments for the cell materials to measure the photon-phonon-photon spectra at different semiconductor layers, and optimise the detector response to these spectra, i.e. choosing the best thermal environment-detector response couple. Overall, the combined fit of the detector responses to the incoming solar spectrum and the emerging spectra through each semiconductor layer should be optimised to maximise collected photocurrent. This is achieved by measuring the emerging spectrum behind each semiconductor layer and by adjusting the detector response of the next semiconductor layer to match with this spectrum as well as possible.

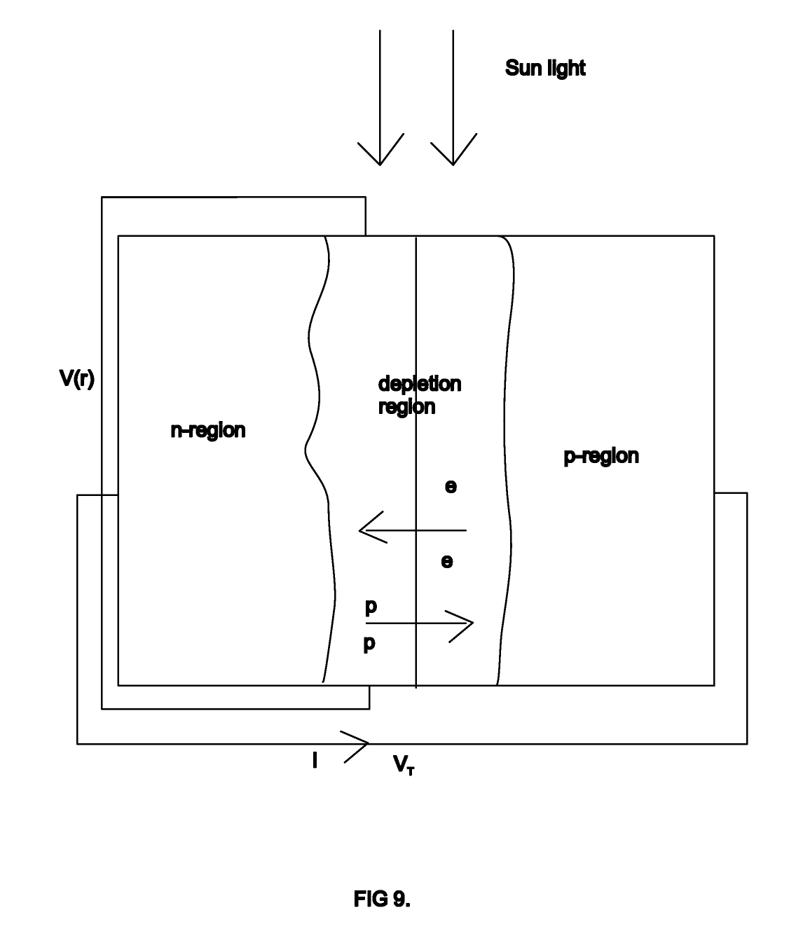

FIG. 9 shows an embodiment of the p-n junction of the invention in detail. Sunlight enters the junction from top of page as indicated by the arrows. The incident sunlight causes a depletion region in the p-n junction as photons of sufficient energy excite electrons over the band gap. Electron-hole pairs are thus generated more or less uniformly within the depletion region. The electrons are swept rapidly into the n-type region by the large electric field in the depletion region. Similarly the holes generated in the depletion region are swept to the p-type region. This is the prompt photocurrent. In addition electron and holes on respective sides may enter the depletion region by diffusion, provided they are within the diffusion distance. This is the slower diffusion photocurrent. The photocurrent can produce the current I with the voltage Vₜ that can be used to do external work, i.e. drive a load.

Now in the invention, a further ambient voltage V is provided, which may vary as a function of position shown as V(r) in FIG. 9 in some embodiments, but may also be homogeneous. In the embodiment shown V(r) is set perpendicular to the photocurrent collection (Vₜ). It has been established in current literature that Vₜ does not affect the band gap of the material. However, what has not been established is that the V(r) would not be able to have an effect on the apparent band gap experienced by the incoming photon flux. Indeed V(r) is designed to change this apparent band gap. V(r) does this by changing the effective potential or the so called pseudopotential experienced by the valence electrons. Different values of V(r) lead to different apparent band gaps when the response of the conduction band and the valence band to V(r) are different. This may be at least partly because of the nuclear shielding effect: i.e. the electrons on the lower shell levels shield the valence electrons differently at different potential levels and therefore the shift caused in the valence band potential may be different to the shift experienced in the conduction band potential, and their difference i.e. the band gap, is effected by V(r).

It is clear the V(r) might introduce charge migration in the vertical direction of the page, which may be a significant advantage of the invention. The photocurrent is collected in the horizontal direction of the page in FIG. 9, but it is also possible to collect photocurrent in the vertical direction of the page in accordance with the invention. It is also in accordance with the invention that any number of electrodes providing V(r) can be used in connection with any region, the n-region, p-region and/or depletion region. Likewise any number of electrodes can be used to collect the photocurrent I in the horizontal direction of the page. Only one circuit for V(r) and one circuit for Vₜ is drawn for the purposes of clarity, there may be any number of such circuits in accordance with the invention.

It is also clear that the embodiment of FIG. 9 can be used with any light, for example light emerging through another semiconductor layer that has been used to collect photocurrent. It is also clear that I and Vₜ can be used to provide V(r). Ideally in this case both potentials are optimised to maximise the total collected photocurrent and/or power.

The invention has been explained above with reference to the aforementioned embodiments and several commercial and industrial advantages have been demonstrated. The methods and arrangements of the invention increase the efficiency of solar cells. The methods and arrangements of the invention therefore improve the competitiveness of solar energy, and make it more available to people and communities globally.

The invention has been explained above with reference to the aforementioned embodiments. However, it is clear that the invention is not only restricted to these embodiments, but comprises all possible embodiments within the spirit and scope of the inventive thought and the following patent claims.

### REFERENCES

EP 1724 841 A1, Josuke Nakata, “Multilayer Solar Cell”
U.S. Pat. No. 6,320,117, James P. Campbell et al., “Transparent solar cell and method of fabrication”
Solar Electricity, Thomas Markvart, 2^{nd} Edition, ISBN 0-471-98852-9
“An unexpected discovery could yield a full spectrum solar cell, Paul Preuss, Research News, Lawrence Berkeley National Laboratory.

1-18. (canceled)

19. A solar cell comprising at least two semiconductor layers (11, 12, 13, 14, 15, 16, 17) with natural band gaps NB (NB1, NB2, NB3, NB4, NB5, NB6, NB7) arranged to convert incoming photons to electric current,
at least one semiconductor layer is provided with at least one electrode (100, 101, 110, 111, 120, 121),
the first semiconductor layer with natural band gap NB1 is arranged to convert a first photon population from the incident photons to photocurrent and leave a secondary photon population,
the first semiconductor layer (11) is transparent to all or some photons outside the first photon population,
the solar cell comprises at least one second semiconductor layer (12, 13, 14, 15, 16, 17) with a natural band gap NB2 behind the first semiconductor layer,
the at least one second semiconductor layer with a natural band gap NB2 is arranged to convert incoming photons from the secondary photon population to electric current, characterised in that,
the secondary photon population spectrum left by an incident solar spectrum through the first semiconductor layer is arranged known from spectrometer measurements,
the combined fit of the semiconductor layer responses to the incoming solar spectrum and the emerging spectra through each semiconductor layer is arranged optimised to maximise total collected photocurrent.

20. A solar cell as claimed in claim 19, characterised in that, the concentration N or total number of the atom/molecule/ion species in at least one semiconductor layer, layer thickness, or the actual atom/molecule/ion species itself are tuned to maximise the captured photocurrent from the incident sunlight, and the fit of the resulting unabsorbed sunlight spectrum with the response of the next subsequent semiconductor layer.

21. A solar cell as claimed in claim 19, characterised in that, first semiconductor layer (11) is incident on the sunlight and the incident photons have a solar spectrum.

22. A solar cell as claimed in claim 19, characterised in that, there is at least one insulating layer in front of and/or behind the first semiconductor layer (11, 12, 13, 14, 15, 16, 17).

23. A solar cell as claimed in claim 19, characterised in that, the solar cell may comprise any number of semiconductor layers (11, 12, 13, 14, 15, 16, 17) and/or insulating layers.

24. A solar cell as claimed in claim 19, characterised in that, the solar cell comprises at least two semiconductor layers (11, 12, 13, 14, 15, 16, 17) in an order where the bigger band gaps are closer to the incident solar spectrum (200), or the solar cell comprises at least two semiconductor layers (11, 12, 13, 14, 15, 16, 17) with in an order where the smaller band gaps are closer to the incident solar spectrum (200).

25. A solar cell as claimed in claim 19, characterised in that, the solar cell comprises at least one semiconductor layer (11, 12, 13, 14, 15, 16, 17) that further comprises Si, polycrystalline silicon, thin-film silicon, amorphous silicon, Ge, GaAs, GaAlAs, GaAlAs/GaAs, GaP, InGaAs, InP, InGaAs/InP, GaAsP/GaP, CdS, CIS, and/or InGaN.

26. A solar cell as claimed in claim 19, characterised in that, the semiconductor layer (11, 12, 13, 14, 15, 16, 17) is a layer of any material or comprising any material capable of experiencing the photoelectric effect.

27. A method for operating a solar cell, comprising at least two semiconductor layers, and comprising the following steps,
raw solar spectrum is incident on first semiconductor layer with band gap NB1 (600),
photons with energy E<NB1 pass through the first semiconductor layer (620),
photons with energy E>NB1 get absorbed and converted to photocurrent, secondary photons left with E−NB1 remain from the absorbed photons (630),
photons with E<NB1 and secondary photons with energy=E−NB1 are incident on second semiconductor layer with band gap NB2 (640), characterised in that,
the secondary photon population spectrum left by an incident solar spectrum through the first semiconductor layer is known from spectrometer measurements,
the combined fit of the semiconductor layer responses to the incoming solar spectrum and the emerging spectra through each semiconductor layer is optimised to maximise collected photocurrent.

28. A method as claimed in claim 27, characterised in that, the steps 620, 630, 640 are repeated for the subsequent semiconductor layers and natural band gaps.

29. A method for producing a solar cell, comprising at least two semiconductor layers and the following steps,
sunlight is incident on first semiconductor layer with natural band gap NB1 (710), characterised in that,
record spectrum of resulting unabsorbed sunlight through the first semiconductor layer with spectrometer 2 (730),
resulting unabsorbed sunlight is incident on second semiconductor layer with natural band gap NB2 (740),
the combined fit of the semiconductor layer responses to the incoming solar spectrum and the recorded spectra through each semiconductor layer is optimised to maximise collected photocurrent.

30. A method as claimed in claim 29, characterised in that, the concentration N or total number of the atom/molecule/ion species in at least one semiconductor layer, layer thickness, or the actual atom/molecule/ion species itself are tuned to maximise the captured photocurrent from the incident sunlight, and the fit of the resulting unabsorbed sunlight spectrum with the response of the next subsequent semiconductor layer.

31. A solar cell with at least two semiconductor layers, characterised in that,
the first layer closest to incident solar radiation is a InGaP and/or GaN layer (11),
the second layer is a polycrystalline silicon layer and/or InSb layer (12).

32. A solar cell comprising at least one first semiconductor layer (11, 12, 13, 14, 15, 16, 17) with a natural band gap NB (NB1, NB2, NB3, NB4, NB5, NB6, NB7) arranged to convert incoming photons to electric current, characterised in that,
at least one semiconductor layer is provided with at least one electrode (100, 101, 110, 111, 120, 121),
the at least one electrode is arranged to provide an ambient voltage V (V1, V2, V3, V4, V5, V6, V7, V(r)) in the semiconductor layer,
the ambient voltage V is arranged to increase charge migration and thereby increase photocurrent.

33. A solar cell comprising at least one first semiconductor layer (11, 12, 13, 14, 15, 16, 17) with a natural band gap NB (NB1, NB2, NB3, NB4, NB5, NB6, NB7) arranged to convert incoming photons to electric current, characterised in that,
at least one semiconductor layer is provided with at least one electrode (100, 101, 110, 111, 120, 121),
the at least one electrode is arranged to provide an ambient voltage V (V1, V2, V3, V4, V5, V6, V7, V(r)) in the semiconductor layer,
the ambient voltage V is arranged to tune the natural band gap NB to apparent band gap B (B1, B2, B3, B4, B5, B6, B7) by B=NB−V,
the semiconductor layer with apparent band gap B is arranged to convert a first photon population from the incident photons to photocurrent and leave secondary photon population.

34. A solar cell as claimed in claim 32, characterised in that,
a second semiconductor layer (12, 13, 14, 15, 16, 17) is provided with at least one electrode (100, 101, 110, 111, 120, 121),
the at least one electrode is arranged to provide an ambient voltage V (V2, V3, V4, V5, V6, V7) in the second semiconductor layer,
the ambient voltage V is arranged to tune the natural band gap NB to apparent band gap B,
the second semiconductor layer with band gap B is arranged to convert a desired third photon population from the incident secondary photon population to photocurrent and leave a desired fourth photon population.
